(19) United States
(12) Patent Application Publication
(10) Pub. No.: US 2026/0018553 A1
(43) Pub. Date: Jan. 15, 2026

(54) FLIP CHIP LIGHT EMITTING DIODE (LED) INTERCONNECT

(71) Applicant: Dominant Opto Technologies Sdn Bhd., Melaka (MY)

(72) Inventors: LOW TEK BENG, MELAKA (MY); TAN ENG WAH, MELAKA (MY); LIM CHEE SHENG, MELAKA (MY)

(21) Appl. No.: 18/882,487

(22) Filed: Sep. 11, 2024

(30) Foreign Application Priority Data
Jul. 10, 2024 (MY) PI 2024004053

(51) Int. Cl. H01L 23/00; H01L 33/62

(52) U.S. Cl. CPC H01L 24/29; H01L 24/05; H01L 24/32; H10H 20/857; H01L 2224/04026; H01L 2224/05556; H01L 2224/2929; H01L 2224/29339; H01L 2224/29565; H01L 2224/2957; H01L 2224/29624; H01L 2224/29666; H01L 2224/32227

(57) ABSTRACT

Disclosed embodiments provide light-emitting diodes (LEDs) and interconnect structures that employ particularly shaped electrodes and a conductive metal-based adhesive that are selected to provide a flexible, robust interconnect that is capable of resisting lateral shear forces, while maintaining a low bond process temperature that is process compatible with other LED component materials. In a non-limiting aspect, disclosed embodiments employ a barrier coating on the interconnect or bonding materials comprising a conductive metal-based adhesive to inhibit moisture and air contact with the conductive metal-based adhesive, thereby preventing or mitigating migration of metal ions in the conductive metal-based adhesive in operation.

The subject patent application claims priority under 35 U.S.C. § 119 to Malaysia Pat. App. No. PI 2024004053, filed Jul. 10, 2024, and entitled “FLIP CHIP LIGHT EMITTING DIODE (LED) INTERCONNECT,” the entirety of which application is hereby incorporated by reference herein.

### TECHNICAL FIELD

The subject application generally relates to Light Emitting Diodes (LEDs) and more particularly to interconnect structures, devices, and methods therefor.

### BACKGROUND

Light Emitting Diodes (LEDs) employing flip chip interconnects for package assembly process are widely employed. Various interconnection/bonding methods for flip chip LED to LED package housing/substrate are available to manufacturers.

However, some applications require more robust interconnection methods, while maintaining an economical interconnect process. For instance, in automotive applications, cyclic high power (e.g., high thermal load) operation of selected LEDs require the interconnect to be compatible with repeated thermal cycles with the ability to withstand stresses associated with operation and usage, with consideration for existing or preferred processes and materials employed in the manufacture of such LEDs.

It is thus desired to provide LEDs and interconnect structures that meet or exceed these and other process and operational constraints. The above-described deficiencies are merely intended to provide an overview of some of the problems of conventional implementations and are not intended to be exhaustive. Other problems with conventional implementations and techniques and corresponding benefits of the various aspects described herein may become further apparent upon review of the following description.

### SUMMARY

The following presents a simplified summary of the specification to provide a basic understanding of some aspects of the specification. This summary is not an extensive overview of the specification. It is intended to neither identify key or critical elements of the specification nor delineate any scope particular to any embodiments of the specification, or any scope of the claims. Its sole purpose is to present some concepts of the specification in a simplified form as a prelude to the more detailed description that is presented later.

In a non-limiting example, disclosed embodiments provide LEDs and interconnect structures, devices, systems, and methods. Disclosed embodiments employ particularly shaped electrodes and a conductive metal-based adhesive that are selected to provide a flexible, robust interconnect that is capable of resisting lateral shear forces, while maintaining a low bond process temperature that is process compatible with other LED component materials. In a non-limiting aspect, disclosed embodiments employ a barrier coating on the interconnect or bonding materials comprising a conductive metal-based adhesive to inhibit moisture and air contact with the conductive metal-based adhesive, thereby preventing or mitigating migration of metal ions in the conductive metal-based adhesive in operation.

These and other embodiments are described in more detail below.

### BRIEF DESCRIPTION OF THE DRAWINGS

Various non-limiting embodiments are further described with reference to the accompanying drawings in which:

FIG. 1 depicts a side view of an exemplary operating environment comprising a non-limiting Light Emitting Diode (LED) package suitable for incorporation of various aspects of the disclosed subject matter;

FIG. 2 depicts a non-limiting apparatus that illustrates contextual aspects of the disclosed subject matter regarding an Anisotropic Conductive Adhesive/Film (ACF);

FIG. 3 illustrates further contextual aspects of the disclosed subject matter regarding flip chip LED bottom electrode designs and construction;

FIG. 4 illustrates potential complications with flip chip LED bottom electrode designs employing nonmetallic interconnection methods, according to aspects of the subject disclosure;

FIG. 5 illustrates further potential complications with flip chip LED bottom electrode designs employing nonmetallic interconnection methods, according to aspects of the subject disclosure;

FIG. 6 depicts exemplary aspects of the disclosed subject matter regarding flip chip LED bottom electrode designs, according to non-limiting embodiments of the subject disclosure;

FIG. 7 depicts further aspects of the disclosed subject matter regarding flip chip LED bottom electrode designs, according to non-limiting embodiments of the subject disclosure;

FIG. 8 depicts still further aspects of the disclosed subject matter regarding flip chip LED bottom electrode designs, according to non-limiting embodiments of the subject disclosure;

FIG. 9 depicts non-limiting embodiments of the subject disclosure regarding non-metallic LED interconnects and packages, according to aspects of the subject disclosure; and

FIG. 10 depicts further non-limiting embodiments of the subject disclosure regarding non-metallic LED interconnects and packages, according to aspects of the subject disclosure.

### DETAILED DESCRIPTION

### Overview

While a brief overview is provided, certain aspects of the subject disclosure are described or depicted herein for the purposes of illustration and not limitation. Thus, variations of the disclosed embodiments as suggested by the disclosed apparatuses, systems, and methodologies are intended to be encompassed within the scope of the subject matter disclosed herein.

As described in background, LEDs employing flip chip interconnects for package assembly process are widely employed, with various interconnection/bonding methods for flip chip LED to LED package housing/substrate being available to manufacturers. Some applications, such as automotive applications, for example, require more robust interconnection methods, because cyclic high power (e.g., high thermal load) operation of selected LEDs require the interconnect to be compatible with repeated thermal cycles and have the ability to withstand stresses associated with operation and usage.

According to one non-limiting aspect, exemplary interconnect or bonding materials can comprise a conductive metal-based adhesive (e.g., a metallic particle filled conductive adhesive), such as silver-filled, electrically conductive adhesive that can facilitate a flexible joint/bond formation of an exemplary LED package, between LED package substrate pads of an LED package substrate and flip chip LED device electrodes or terminals of a flip chip LED device 106 that accommodates LED package components having otherwise incompatible differences in coefficients of thermal expansion (CTE), as described herein, regarding formation of metallic-based solder joint/bonds. In further non-limiting aspects, exemplary interconnect or bonding materials comprising conductive metal-based adhesive (e.g., a metallic particle filled conductive adhesive), such as silver-filled, electrically conductive adhesive can facilitate a low bonding temperatures (e.g., less than about 180° C.), which might otherwise cause exemplary LED packaging component materials thermal degradation, as further described herein, regarding formation of metallic-based solder joint/bonds.

In addition, in other non-limiting aspects, interconnect or bonding materials comprising conductive metal-based adhesive (e.g., a metallic particle filled conductive adhesive), such as silver-filled, electrically conductive adhesive can, in conjunction with a variety of shaped flip chip LED device electrodes or terminals designs, withstand lateral shear forces that might otherwise result in adhesive delamination, as described herein, regarding formation of metallic particle filled conductive adhesive joint/bonds with particular electrode designs for metallic-based solder joint/bonds. Moreover, in further non-limiting aspects, exemplary interconnect or bonding materials comprising conductive metal-based adhesive (e.g., a metallic particle filled conductive adhesive), such as silver-filled, electrically conductive adhesive can mitigate or prevent, in conjunction with a protective, moisture/air barrier coating on the exemplary interconnect or bonding materials comprising conductive metal-based adhesive (e.g., a metallic particle filled conductive adhesive), metal migration in the exemplary interconnect or bonding materials, which could otherwise lead to exemplary LED package failure, as further described herein, regarding formation of metallic particle filled conductive adhesive joint/bonds and metallic-based solder joint/bonds (e.g., sintered silver joint/bond).

To these and/or related ends, various aspects of LED device interconnection means, devices, systems, and methods therefor are described. Various embodiments of the subject disclosure are described herein for purposes of illustration, and not limitation. For example, embodiments of the subject disclosure are described herein in the context of LED interconnections. However, it can be appreciated that the subject disclosure is not so limited. However, as further detailed below, various exemplary implementations can be applied to other areas of interconnection structures, without departing from the subject matter described herein.

For example, the various embodiments of the apparatuses, techniques, and methods of interconnect construction may be employed in any of a number of devices including, but not limited to other high power flip chip devices, and so on, as further described herein.

### Exemplary Embodiments

Various aspects or features of the subject disclosure are described with reference to the drawings, wherein like reference numerals are used to refer to like elements throughout. In this specification, numerous specific details are set forth in order to provide a thorough understanding of the subject disclosure. It should be understood, however, that certain aspects of disclosure may be practiced without these specific details, or with other methods, components, parameters, etc. In other instances, well-known structures, components, and so on are shown in block diagram form to facilitate description and illustration of the various embodiments.

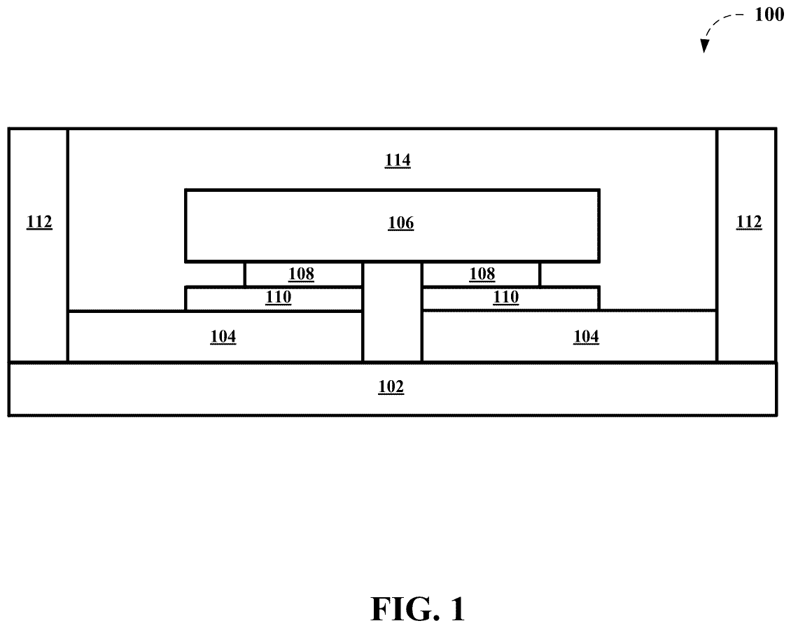

FIG. 1 depicts a side view of an exemplary operating environment comprising a non-limiting Light Emitting Diode (LED) package suitable for incorporation of various aspects of the disclosed subject matter. For example, an exemplary LED package 100 can comprise an LED package substrate 102 having a set of LED package substrate pads 104 for electrical coupling and mechanical bonding of an exemplary flip chip LED device 106 via a set of respective flip chip LED device 106 electrodes or terminals 108. It is understood that one of flip chip LED device 106 electrodes or terminals 108 can comprise an anode or positive electrode or terminal 108 and another can comprise a cathode or negative positive electrode or terminal 108 (not shown).

Exemplary flip chip LED device 106 can be attached and electrically coupled to LED package substrate 102 via an interconnect or bonding material 110, a variety of which are described herein as an aid to understanding various aspects of the disclosed subject matter. Exemplary LED package 100 can further comprise an LED housing 112, comprising a material that can be selected for its thermal stability, as further described herein. In addition, an exemplary LED package 100 can comprise an optically clear transmission material 114 such as a high-transmittance resin, for efficient transmission of light generated by flip chip LED device 106.

Exemplary LED package 100 can comprise any of a number of different interconnect or bonding materials 110, the advantages and disadvantages of which are now described. For instance, an interconnect or bonding material 110 can comprise a metallic-based solder joint/bond, a variety of which are described herein. An exemplary interconnect or bonding material 110 comprising a metallic-based solder joint/bond can be formed by bringing a selected metal bonding material above liquidous temperature and then subsequently cooling it down below solidus temperature.

As non-limiting examples, metallic-based solder joint/bond interconnect or bonding materials 110 can include gold-tin (e.g., 80 percent (%) gold (Au), 20% tin (Sn)) solder, tin-silver-copper SAC solder (e.g., Sn, silver (Ag), copper (Cu)), and sintered silver. Exemplary interconnect or bonding material 110 comprising gold-tin solder can be prohibitively expensive given that gold loading in the solder interconnect or bonding material 110 can be as high as 80% of solder interconnect or bonding material 110 by weight. In addition, 80 percent (%) Au, 20% Sn solder has melting point of 282 degrees (°) Celsius (C), which can require bonding temperatures in excess of 300° C. for an acceptable solder joint/bond.

However, such high bonding temperatures can negatively impact the selection of materials employed in LED package substrate 102 and/or LED housing 112. For instance, materials selected for LED housing 112 are typically limited to costly ceramic materials, which can withstand high temperature processing without thermal degradation or degrade in optical reflectivity what would result in reduced LED package intensity. In addition, because a typical Au—Sn solder joint/bond is hard in nature (hardness of approximately 42.5 Brinell Hardness (HB)), an exemplary flip chip LED device 106 is required to have a coefficient of thermal expansion (CTE) closely matching the Au—Sn joint/bond CTE and LED package substrate 102 CTE to ensure no solder joint/bond cracking as a result of repeated thermal cycling during operations, which could lead to catastrophic failure of exemplary LED package 100. As can be understood, the requirement for CTE matching among exemplary LED package 100 components limits the type of material that can be used to assemble the LED package, including, but not limited to the interconnect or bonding material 110.

It can be further understood that an interconnect or bonding material 110 comprising an Au—Sn metallic solder joint/bond desired where the LED package has to go through reflow process again during surface mounting process to attach the LED package to a printed circuit board. That is, because the high melting temperature of the Au—Sn joint/bond, it will prevent secondary reflow from occurring during user surface mounting process using common SAC base solder material as described herein. As a result, gold-tin solder bonding is desired for situations that have operating conditions of high-power rating and high operating temperature range, such as, for example, for automotive grade flip chip LED package 100.

In another non-limiting aspect, exemplary interconnect or bonding material 110 can comprise SAC base solder (e.g., Tin-Silver-Copper), which can also be used in exemplary LED package 100 surface mounting processes. However, melting points of SAC base solder depends on the silver/copper content and other trace metal loading, thus, the melting temperatures vary in the range of 200° C. to 230° C. In addition, SAC base solder joint/bond is softer compared to Au—Sn solder joint/bond with hardness in the range of 15 HB. While SAC solder can offer a good balance in term of cost and performance, standard LED packages for automotive application typically need to subsequently go through surface mounting processes, in which exemplary LED packages 100 can be exposed to in excess of 210° C. during the reflow process.

At these temperatures, it can be expected that the SAC solder joint/bond can re-melt. Moreover, exemplary LED packages 100 surrounded by optically clear transmission material 114, which can comprise a silicone polymer with high refractive index to enhance light extraction from flip chip LED device 106. It can be further understood that an optically clear transmission material 114 comprising this type of resin can have a large CTE (e.g., in excess of 200 parts per million (ppm)/° C.) above material glass transition point, versus SAC solder (e.g., having CTE of 21 ppm/° C.).

Thus, when re-melting of a SAC solder joint/bond during exemplary LED package 100 surface mount solder reflow to an underlying printed circuit board (PCB), the flip chip LED device 106 could be pushed away from its intended bonding area. Under mild conditions, voids can form within the interconnect or bonding material 110 comprising the SAC solder joint/bond, which can reduce contact area of the joint/bond and weaken the mechanical bond provided by the interconnect or bonding material 110. Under severe conditions, the SAC solder joint/bond could break down, causing a lack of electrical coupling of the flip chip LED device 106 to the LED package substrate 102 (e.g., resulting in a continuity open). As a result, bonding of flip chip LED device 106 using SAC base solder is not desirable in situations that require robust interconnection methods, such as automotive applications, for example.

Exemplary interconnect or bonding material 110 comprising silver sintered bonding can utilize both pressure and heat to fuse silver nanoparticles during the joint/bond forming process, which bonding process allows forming joint/bond which a has high melting point (e.g., silver melting point is approximately 962° C.). However, silver sintered bonding requires long processing times, which require pressure to be applied to flip chip LED device 106 for a defined duration, raising processing costs. For instance, silver sintered process temperatures can be in excess of 220° C. Otherwise, a weak silver sintered joint/bond with high porosity can result. This process temperature has the potential to degrade conventional materials employed in LED housing 112, which is formulated by engineering plastic. In addition, since silver is a highly active metal, under high heat and in a high moisture environment, silver can dissolve to become Ag+ ions, which can migrate across flip chip LED device 106 electrodes or terminals 108 under the effect of electrical potential difference between LED anode and cathode LED. It can be understood that such silver migration can lead to device leakage and shorting that eventually render exemplary LED package 100 inoperative.

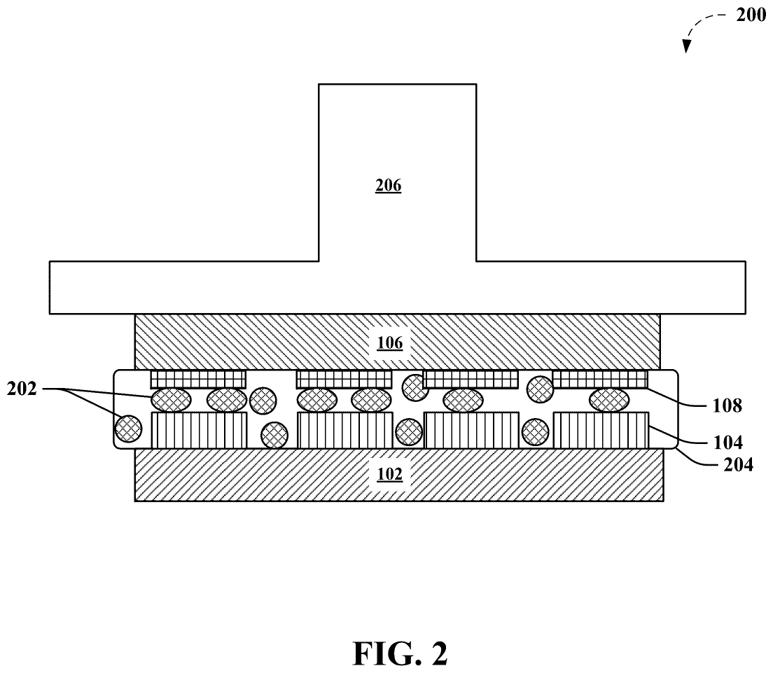

FIG. 2 depicts a non-limiting apparatus 200 that illustrates contextual aspects of the disclosed subject matter regarding an Anisotropic Conductive Adhesive/Film (ACF), which illustrates aspect of joint/bond formation of exemplary LED package 100, between LED package substrate pads 104 of LED package substrate 102 and flip chip LED device 106 electrodes or terminals 108 of flip chip LED device 106. Thus, FIG. 2 depicts an exemplary interconnect or bonding material 110 comprising a non-limiting example of a nonmetallic joint/bond, which can be formed by loading of metal particles 202 in an adhesive material 204 to enhance electrical and thermal conductivity of the adhesive carrier substance. Conventionally, a suitable adhesive material is applied in a liquid or semi-solid form to ease of processing, which adhesive material is then heat cured (usually with pressure applied via a device chuck 206) or ultraviolet (UV) cured to form a solid state that mechanically binds the LED package substrate pads 104 of LED package substrate 102 to flip chip LED device 106 electrodes or terminals 108 of flip chip LED device 106, to form the mechanical bond.

Accordingly, FIG. 2 depicts an exemplary LED package 100 having an interconnect or bonding material 110 comprising an Anisotropic Conductive Adhesive/Film (ACF), which can use nickel or silver metal particles 202 embedded in adhesive material 204 comprising an adhesive polymer, in one non-limiting example. Advantageously, ACF is flexible compared to the more rigid metallic-based joint/bond. As a result, CTE matching between different materials in the exemplary LED package 100 is not as crucial, leading to more reliable performance under cyclic thermal conditions.

It can be understood that electrical conductivity and thermal conductivity of interconnect or bonding material 110 comprising ACF depends on metal particle 202 loading. Accordingly, because metal particle 202 loading in ACF is typically limited, interconnect or bonding material 110 comprising ACF has relatively low electrical conductivity and low thermal conductivity, which limits the use of ACF for lower power LED applications (e.g., applications having low operating current and/or limited operating temperature range). Thus, ACF is not desirable in situations that require robust interconnection methods, such as automotive applications, for example, which have higher thermal and power loads while operating temperatures range from −40° C. to 125° C. In addition, interconnect or bonding material 110 comprising ACF, as with interconnect or bonding material 110 comprising sintered silver, requires heat, pressure, and time to form a good joint/bond, limiting its economic utility.

In another non-limiting aspect, exemplary interconnect or bonding material 110 can comprise a conductive metal-based adhesive (e.g., a metallic particle filled conductive adhesive), which can comprise a silver-based glue with high silver metal particle 202 loading is common type of adhesive material 204. It can be understood that there are tradeoffs between requirements for adhesion strength of the joint/bond as compared to requirements for joint/bond electrical and thermal conductivity. Thus, the higher the metal particle 202 loading in the adhesive material 204, the higher the electrical and thermal conductivity, while the joint/bond strength is sacrificed, due to less adhesive material 204 volume for bonding the LED package substrate pads 104 of LED package substrate 102 to flip chip LED device 106 electrodes or terminals 108 of flip chip LED device 106.

Exemplary interconnect or bonding material 110 can comprise a conductive metal-based adhesive (e.g., a metallic particle filled conductive adhesive). For instance, a conductive metal-based adhesive (e.g., a metallic particle filled conductive adhesive) can be suitable for bonding large flip chip LED devices 106, which have large flip chip LED device 106 electrodes or terminals 108 surface areas to ensure sufficient bonding strength. However, for relatively smaller flip chip LED devices 106, e.g., where anode and cathode flip chip LED device 106 electrodes or terminals 108 is of limited surface area, bonding strength between the flip chip LED device 106 electrodes or terminals 108 to LED package substrate 102 could be insufficient to provide a reliable and robust joint/bond.

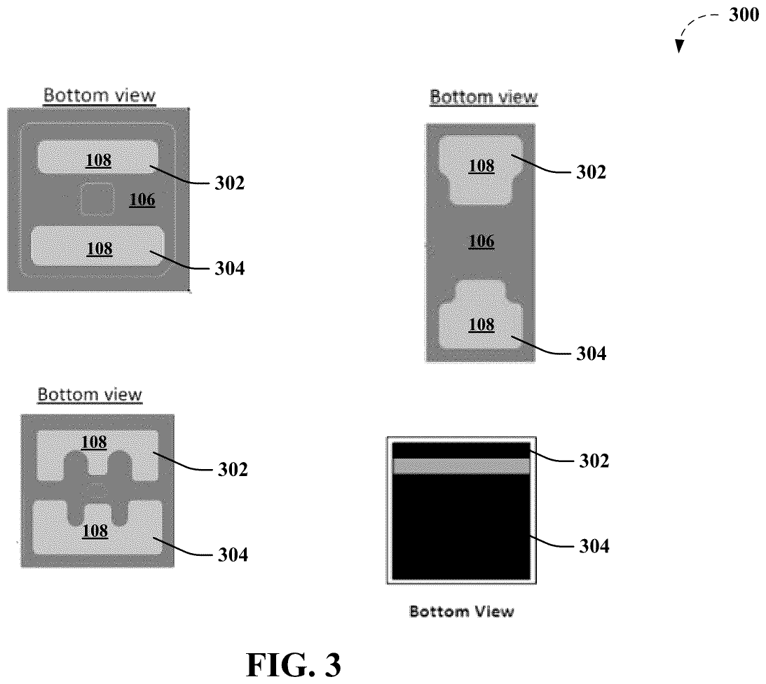

For instance, FIG. 3 illustrates further contextual aspects of the disclosed subject matter regarding flip chip LED bottom electrode designs and construction. FIG. 3 depicts bottom views 300 of exemplary flip chip LED devices 106, where the flip chip LED device 106 electrodes or terminals 108 can comprise an anode 302, or positive electrode or terminal 108, and another can comprise a cathode 304, or negative positive electrode or terminal 108. Several non-limiting characteristics of flip chip LED device 106 electrodes or terminals 108 are apparent from FIG. 3, such as that anode 302 and cathode 304 solder terminal having flat bottom surfaces to facilitate metal base joint/bond forming, e.g., Au—Sn solder, SAC solder, sintered silver) and that anode 302 and cathode 304 flip chip LED device 106 electrodes or terminals 108 are enlarged to the extent allowed within applicable design rules to enhance electrical conductivity and reduce thermal resistance after forming the solder joint/bond. Nevertheless, such anode 302 and cathode 304 flip chip LED device 106 electrodes or terminals 108 provide a relatively smaller bonding surface area.

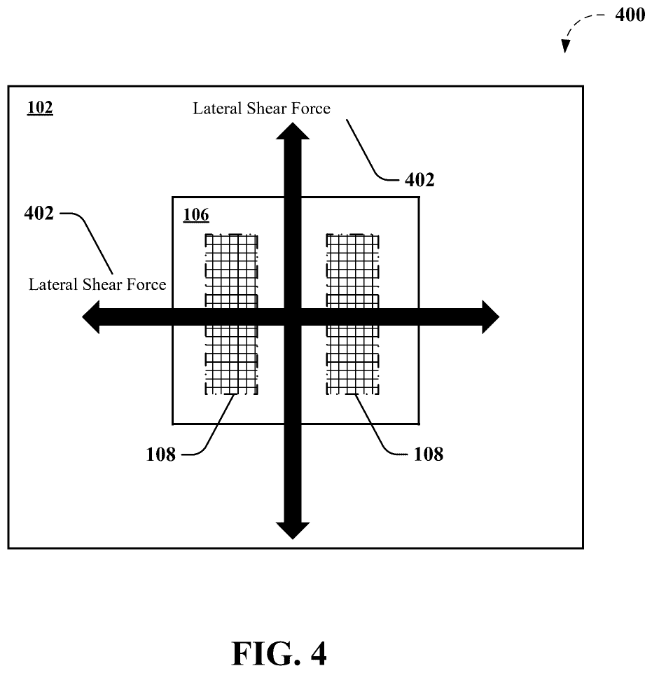

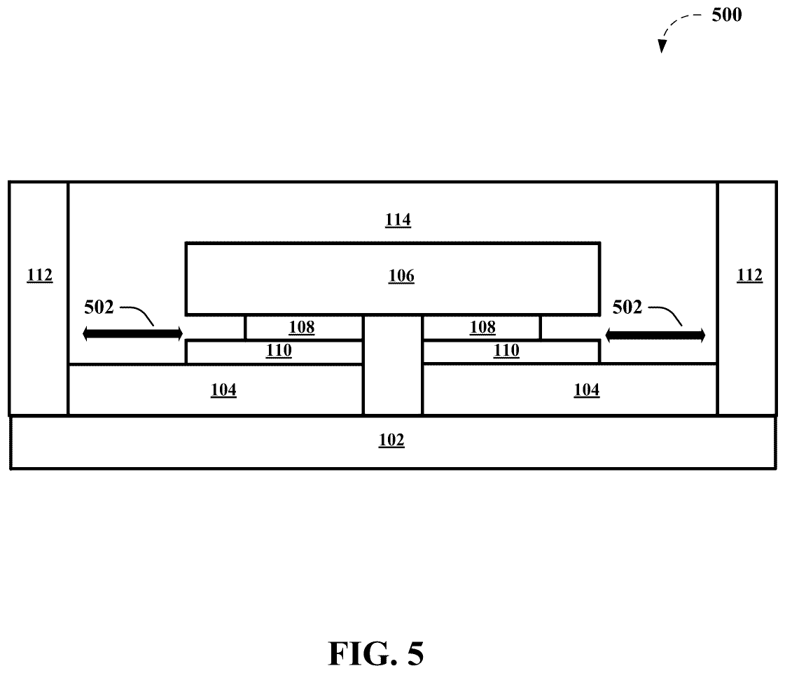

Thus, as further described herein regarding FIGS. 4-5, When lateral force is applied to the joint/bond interconnect or bonding material 110 interface during thermal cycling, the joint/bond could delaminate and result in an exemplary LED package 100 electrical open failure. In addition, as with silver sintered bonding as described above, a conductive metal-based adhesive (e.g., a metallic particle filled conductive adhesive) with high silver particle loading is prone to the silver migration problem in the presence of high heat and high moisture around the interconnect or bonding material 110, when coupled with electrical potential different between anode and cathode flip chip LED device 106 electrodes or terminals 108 during normal LED package 100 operation. For instance, as described above, exemplary LED package 100 is typically surrounded by optically clear transmission material 114 (e.g., optically clear resin, a silicone polymer with high porosity) exemplary LED package 100 can be permeable to the moisture and/or ionic impurity from the surrounding environment, which could accelerate the silver migration problem.

Thus, the failure risk of using heavy silver particle loading in a conductive metal-based adhesive (e.g., a metallic particle filled conductive adhesive) for small flip chip LED device 106 bonding is high, without more. As a result, for situations that require robust interconnection methods, such as automotive applications, for example, which have higher thermal and power loads, heavy silver particle loading in a conductive metal-based adhesive (e.g., a metallic particle filled conductive adhesive) for small flip chip LED devices 106 are avoided to mitigate such risk.

Nevertheless, one advantage of conductive metal-based adhesive (e.g., a metallic particle filled conductive adhesive) is that the joint/bond is relatively more flexible, allowing for use as an interconnect or bonding material 110 for devices having component materials with different CTE. As another advantage, conductive metal-based adhesive (e.g., a metallic particle filled conductive adhesive) requires curing at temperatures less than about 180° C., which is process compatible with materials employed in LED housing 112 without risk of degradation of such materials.

For example, FIG. 4 illustrates potential complications with flip chip LED bottom electrode designs employing nonmetallic interconnection methods, according to aspects of the subject disclosure. For instance, FIG. 4 depicts a bottom view 400 of an exemplary flip chip LED devices 106, where the flip chip LED device 106 electrodes or terminals 108 are depicted as exposed to lateral shear force 402.

As described above, regarding FIG. 3, for example, flip chip LED device 106 electrodes or terminals 108 designs that are useful for metallic-based solder joint/bond interconnect or bonding material 110, where joint/bond formation is by a mechanism of interdiffusion of interfacial metallic layer during high temperature soldering, may not be adequate for application for nonmetallic joint/bond interconnect or bonding material 110, such as for an interconnect or bonding material 110 comprising a conductive metal-based adhesive (e.g., a metallic particle filled conductive adhesive) as further described herein.

Thus, FIG. 5 illustrates further potential complications with flip chip LED bottom electrode designs employing nonmetallic interconnection methods, according to aspects of the subject disclosure. For instance, FIG. 5 depicts a side view 500 of the exemplary LED package 100 in the presence of a lateral shear force 502. However, if conductive metal-based adhesive (e.g., a metallic particle filled conductive adhesive), such as a silver particle-filled adhesive, is used as an interconnect or bonding material 110 to form the joint/bond using the flip chip LED device 106 electrodes or terminals 108 designs employed for metallic-based solder joint/bond interconnect or bonding material 110, then mechanical strength of the joint/bond can be insufficient withstand lateral shear force 502 (e.g., from normal operation thermo-mechanical stress and strain), potentially resulting in delamination of the flip chip LED device 106 electrodes or terminals 108 from the LED package substrate pads 104 of LED package substrate 102.

Thus, according to various non-limiting embodiments, the subject disclosure provides flip chip LED device 106 to LED package substrate 102 interconnect or bonding materials 110, structures, and methods that provide enhanced bonding strength and metal migration resistance using exemplary interconnect or bonding materials 110 comprising conductive metal-based adhesive (e.g., a metallic particle filled conductive adhesive), such as silver-filled, electrically conductive adhesive, in conjunction with a variety of shaped flip chip LED device 106 electrodes or terminals 108 designs, and a protective, moisture/air barrier coating to be employed with the provided interconnect or bonding materials 110.

According to one non-limiting aspect, exemplary interconnect or bonding materials 110 comprising conductive metal-based adhesive (e.g., a metallic particle filled conductive adhesive), such as silver-filled, electrically conductive adhesive can facilitate a flexible joint/bond formation of exemplary LED package 100, between LED package substrate pads 104 of LED package substrate 102 and flip chip LED device 106 electrodes or terminals 108 of flip chip LED device 106 that accommodates LED package 100 components having otherwise incompatible differences in CTE, as described above, regarding formation of metallic-based solder joint/bonds.

In further non-limiting aspects, exemplary interconnect or bonding materials 110 comprising conductive metal-based adhesive (e.g., a metallic particle filled conductive adhesive), such as silver-filled, electrically conductive adhesive can facilitate a low bonding temperatures (e.g., less than about 180° C.), which might otherwise cause exemplary LED packaging 100 component materials thermal degradation, as described above, regarding formation of metallic-based solder joint/bonds. In addition, in other non-limiting aspects, interconnect or bonding materials 110 comprising conductive metal-based adhesive (e.g., a metallic particle filled conductive adhesive), such as silver-filled, electrically conductive adhesive can, in conjunction with a variety of shaped flip chip LED device 106 electrodes or terminals 108 designs, withstand lateral shear forces 402, 502 that might otherwise result in adhesive delamination, as described above, regarding formation of metallic particle filled conductive adhesive joint/bonds with particular electrode designs for metallic-based solder joint/bonds.

Moreover, in further non-limiting aspects, exemplary interconnect or bonding materials 110 comprising conductive metal-based adhesive (e.g., a metallic particle filled conductive adhesive), such as silver-filled, electrically conductive adhesive can mitigate or prevent, in conjunction with a protective, moisture/air barrier coating on the exemplary interconnect or bonding materials 110 comprising conductive metal-based adhesive (e.g., a metallic particle filled conductive adhesive), metal migration in the exemplary interconnect or bonding materials 110, which could otherwise lead to exemplary LED package 100 failure, as described above, regarding formation of metallic particle filled conductive adhesive joint/bonds and metallic-based solder joint/bonds (e.g., sintered silver joint/bond).

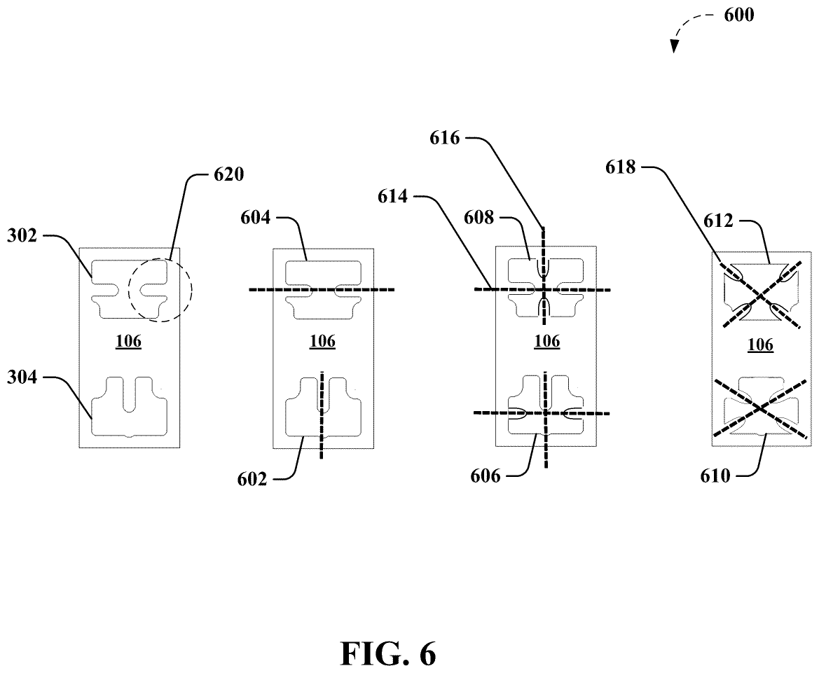

Accordingly, FIG. 6 depicts exemplary aspects of the disclosed subject matter regarding flip chip LED bottom electrode designs 600, according to non-limiting embodiments of the subject disclosure. As described above, interconnect or bonding materials 110 comprising conductive metal-based adhesive (e.g., a metallic particle filled conductive adhesive), such as silver-filled, electrically conductive adhesive can, in conjunction with a variety of shaped flip chip LED device 106 electrodes or terminals 108 designs, withstand lateral shear forces 402, 502 that might otherwise result in adhesive delamination, as described above, regarding formation of metallic particle filled conductive adhesive joint/bonds with particular electrode designs for metallic-based solder joint/bonds.

Thus, FIG. 6 depicts bottom views of flip chip LED device 106 electrodes or terminal 108 designs 600, in which the shaped electrodes or terminals 108 (e.g., shaped electrodes 602, 604, 606, 608, 610, 612) are attached to flip chip LED device 106. In another non-limiting aspect, shaped electrodes 602, 604, 606, 608, 610, 612 can comprise any of a number of different lateral shapes (e.g., depicted by shaped electrodes 602, 604, 606, 608, 610, 612, or otherwise) that can be selected or designed to resist lateral shear forces 402, 502 applied between the flip chip LED device 106 and LED package substrate 102.

For instance, FIG. 6 depicts lateral forces 402, 502 applied in a horizontal orientation 614, a vertical orientation 616, and a diagonal orientation 618. While it can be understood that such lateral shear forces 402, 502 can originate in practically any orientation, these depictions are provided as an aid to understanding the disclosed subject matter. Thus, it can be appreciated that shaped electrodes 602, 604, 606, 608, 610, 612 are designed to provide an increase in perimeter of the surface shown (e.g., the surface opposite the flip chip LED device 106) of the shaped electrodes 602, 604, 606, 608, 610, 612, relative to a square or a rectangular shaped electrode.

In addition, such shaped electrodes 602, 604, 606, 608, 610, 612 lateral shapes that are selected to resist lateral shear forces applied between the flip chip LED device 106 and LED package substrate 102 in the direction (e.g., horizontal orientation 614, vertical orientation 616, and diagonal orientation 618) of the lateral forces 402, 502 applied, by arranging the protrusions of the perimeter increase of the shaped electrodes 602, 604, 606, 608, 610, 612 in the direction of the anticipated lateral forces 402, 502 to be resisted (e.g., horizontal orientation 614, vertical orientation 616, and diagonal orientation 618). Thus, by increasing the perimeter of the shaped electrodes 602, 604, 606, 608, 610, 612 lateral shapes and by orienting such perimeter increasing protrusion in the direction of direction of the anticipated lateral forces 402, 502 to be resisted (e.g., horizontal orientation 614, vertical orientation 616, and diagonal orientation 618), resistance to anticipated lateral forces 402, 502 can be increased.

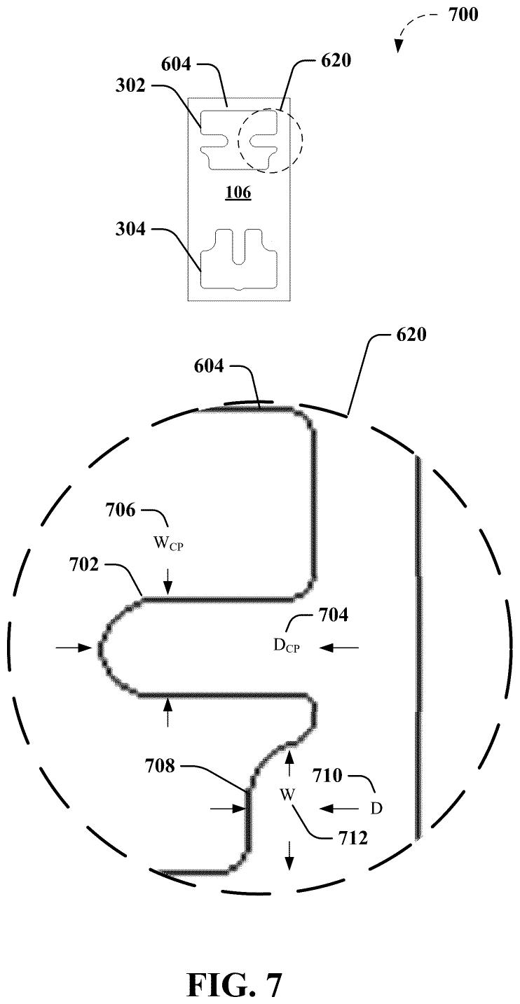

FIG. 6 further depicts inset 620, which, in conjunction with FIG. 7, illustrates further aspects of the disclosed subject matter regarding flip chip LED bottom electrode designs 600. For instance, FIG. 7 depicts 700 further aspects of the disclosed subject matter regarding flip chip LED bottom electrode designs 600, according to non-limiting embodiments of the subject disclosure. As described above, shaped electrodes 602, 604, 606, 608, 610, 612 can comprise any of a number of different lateral shapes (e.g., depicted by shaped electrodes 602, 604, 606, 608, 610, 612, or otherwise) that can be selected or designed to resist lateral shear forces 402, 502 applied between the flip chip LED device 106 and LED package substrate 102.

In FIG. 7, an aspect ratio (A_{cp}) for a particular perimeter increasing protrusion of convex portion 702 can be defined as D_{cp}/W_{cp}, where D_{cp} 704 is the depth of the perimeter increasing protrusion from the where the edge of the shaped electrode 604 would be but for the perimeter increasing protrusion of convex portion 702, and where W_{cp} 706 is the width of the perimeter increasing protrusion of convex portion 702. Thus, inset 620 of FIG. 7, shows that by increasing the perimeter of the shaped electrodes 602, 604, 606, 608, 610, 612 lateral shapes and by orienting such perimeter increasing protrusion (e.g., perimeter increasing protrusion of convex portion 702) in the direction of the anticipated lateral forces 402, 502 to be resisted (e.g., horizontal orientation 614, vertical orientation 616, and diagonal orientation 618), resistance to anticipated lateral forces 402, 502 can be increased.

Note that the perimeter increasing protrusion of convex portion 702 of the shaped electrode 604 lateral shape is selected to resist lateral shear forces by increasing the perimeter of the lateral shape and in the direction of the in the direction of the anticipated lateral forces 402, 502 to be resisted (e.g., horizontal orientation 614). Such perimeter increasing protrusion of convex portion 702 that are selected to resist lateral shear forces can be distinguished from other convex portions 708, in that the A_{cp} (e.g., about 2.5) for perimeter increasing protrusion of convex portion 702 is generally much greater than A (e.g., about 1.0), where D 710 is approximately equal to W 712, for convex portion 708 (e.g., generally quarter circle-shaped). While convex portion 708 can be said to increase perimeter of shaped electrode 604 surface opposite the flip chip LED device 106, it is not necessarily selected to resist lateral shear forces (e.g., resist lateral shear forces 402, 502) in any particular direction. Accordingly, in an aspect, non-limiting embodiments of the disclosed subject matter can employ a shaped electrode (e.g., shaped electrodes 602, 604, 606, 608, 610, 612) attached to an LED device (e.g., flip chip LED device 106).

In another non-limiting aspect, the shaped electrode (e.g., shaped electrodes 602, 604, 606, 608, 610, 612) comprises a lateral shape that is selected to resist lateral shear forces (e.g., lateral shear forces 402, 502) applied between the LED device (e.g., flip chip LED device 106) and a LED package substrate (e.g., LED package substrate 102), based an increase in perimeter (e.g., via a perimeter increasing protrusion such as a perimeter increasing protrusion of convex portion 702) of a surface opposite the LED device (e.g., flip chip LED device 106) associated with the shaped electrode (e.g., shaped electrodes 602, 604, 606, 608, 610, 612). As can be understood, the increase in perimeter (e.g., via a perimeter increasing protrusion such as a perimeter increasing protrusion of convex portion 702) of a surface opposite the LED device (e.g., flip chip LED device 106 is an increase relative to a standard shaped electrode (e.g., square shaped, rectangular shaped, round shaped, oval shaped, polygonal shaped, and so on). In yet another non-limiting aspect, the lateral shape that is selected to resist lateral shear forces (e.g., lateral shear forces 402, 502) applied between the LED device (e.g., flip chip LED device 106) and a LED package substrate (e.g., LED package substrate 102) can comprise a convex portion (e.g., a perimeter increasing protrusion of convex portion 702 or similar) of the perimeter of the surface opposite the LED device (e.g., flip chip LED device 106).

It can be further understood that the shaped electrode (e.g., shaped electrodes 602, 604, 606, 608, 610, 612) can facilitate anchorage of the interconnect or bonding materials 110 comprising conductive metal-based adhesive (e.g., a metallic particle filled conductive adhesive), such as silver-filled, electrically conductive adhesive into the perimeter increasing protrusion of convex portion 702 of the shaped electrode (e.g., shaped electrodes 602, 604, 606, 608, 610, 612) during the bonding process. As described above, this anchorage can enhance the joint/bond resistance against the lateral forces 402, 502.

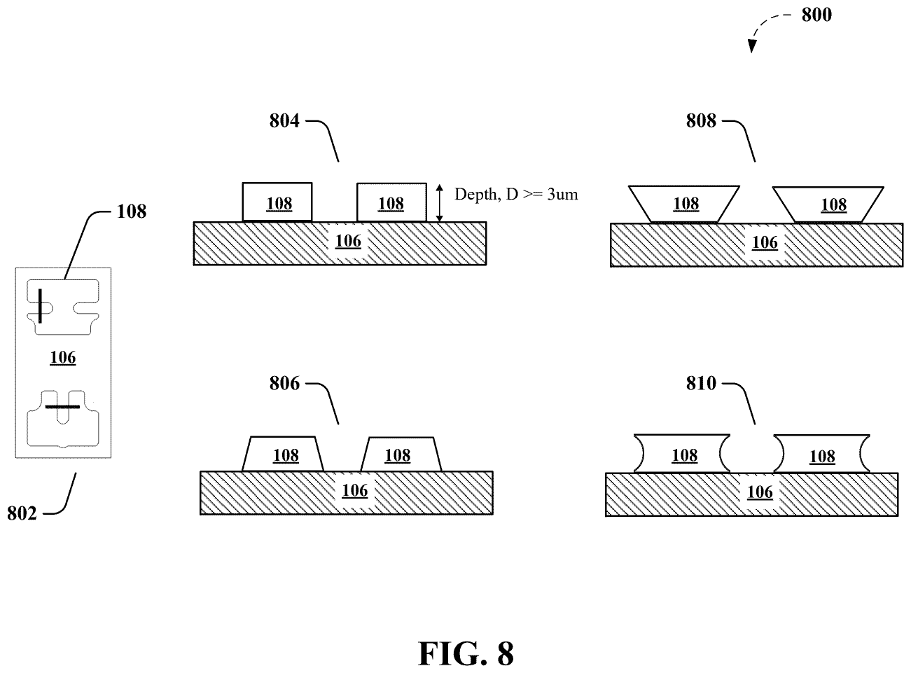

FIG. 8 depicts still further aspects of the disclosed subject matter regarding flip chip LED bottom electrode designs 800, according to non-limiting embodiments of the subject disclosure. For instance, while view 802 of FIG. 8 depicts exemplary shaped electrode (e.g., shaped electrodes 602, 604, 606, 608, 610, 612) in a bottom view of the surface opposite the LED device (e.g., flip chip LED device 106) associated with the shaped electrode (e.g., shaped electrodes 602, 604, 606, 608, 610, 612), views 804, 806, 808, and 810 show the exemplary shaped electrode (e.g., shaped electrodes 602, 604, 606, 608, 610, 612) atop the LED device (e.g., flip chip LED device 106) in side view to illustrate further non-limiting aspects of the disclosed subject matter.

For example, while view 804 depicts a side view of a rectangular or cube-shaped thickness profile of the shaped electrode (e.g., shaped electrodes 602, 604, 606, 608, 610, 612), each of the views 806, 808, and 810 depict thickness profiles that increase surface area of the shaped electrode (e.g., shaped electrodes 602, 604, 606, 608, 610, 612) in a direction orthogonal to the LED device (e.g., flip chip LED device 106), based on the thickness profiles in views 806, 808, and 810 being non-orthogonal to the LED device (e.g., flip chip LED device 106).

For instance, in views 806 and 808, the thickness profile is that of a trapezoid, where the thickness profiles in views 806 and 808 are non-orthogonal to the LED device (e.g., flip chip LED device 106). That is, the sides of the shaped electrode (e.g., shaped electrodes 602, 604, 606, 608, 610, 612) labeled generally as flip chip LED device 106 electrodes or terminals 108 are oblique to a line orthogonal to the surface of the LED device (e.g., flip chip LED device 106. Thus, it can be understood that the surface area of such trapezoidal shapes (e.g., resembling a truncated pyramid for square or rectangular based LED device 106 electrodes or terminals 108, or resembling a truncated cone for circular based LED device 106 electrodes or terminals 108) would have a larger surface area in a direction orthogonal to the LED device (e.g., flip chip LED device 106) than that of shaped electrode (e.g., shaped electrodes 602, 604, 606, 608, 610, 612) in view 804, based on the thickness profiles in views 806, 808 being non-orthogonal to the LED device (e.g., flip chip LED device 106).

In view 810, the surface area of the thickness profile is increased by convex portions of the profile, where the thickness profiles in view 810 is non-orthogonal to the LED device (e.g., flip chip LED device 106). That is, the sides of the shaped electrode (e.g., shaped electrodes 602, 604, 606, 608, 610, 612) labeled generally as flip chip LED device 106 electrodes or terminals 108 are not completely orthogonal to the surface of the LED device (e.g., flip chip LED device 106. Thus, it can be understood that the surface area of such convex portions would have a larger surface area in a direction orthogonal to the LED device (e.g., flip chip LED device 106) than that of shaped electrode (e.g., shaped electrodes 602, 604, 606, 608, 610, 612) in view 804, based on the thickness profile in view 810 being non-orthogonal to the LED device (e.g., flip chip LED device 106).

Thus, in various non-limiting embodiments, the disclosed subject matter provides thickness profiles that increase surface area of the shaped electrode (e.g., shaped electrodes 602, 604, 606, 608, 610, 612) in a direction orthogonal to the LED device (e.g., flip chip LED device 106), based on the thickness profiles in views 806, 808, and 810 being non-orthogonal to the LED device (e.g., flip chip LED device 106) to facilitate bonding between the shaped electrode (e.g., shaped electrodes 602, 604, 606, 608, 610, 612) and LED package substrate pads 104 of LED package substrate 102 via the interconnect or bonding materials 110 comprising conductive metal-based adhesive (e.g., a metallic particle filled conductive adhesive), such as silver-filled, electrically conductive adhesive, with enhanced joint/bond force between the shaped electrode (e.g., shaped electrodes 602, 604, 606, 608, 610, 612) and the interconnect or bonding materials 110 comprising conductive metal-based adhesive (e.g., a metallic particle filled conductive adhesive), such as silver-filled, electrically conductive adhesive, without increasing the depth/thickness of the shaped electrode (e.g., shaped electrodes 602, 604, 606, 608, 610, 612) to the datum of the LED device (e.g., flip chip LED device 106) (e.g., equal or greater than about 3 microns).

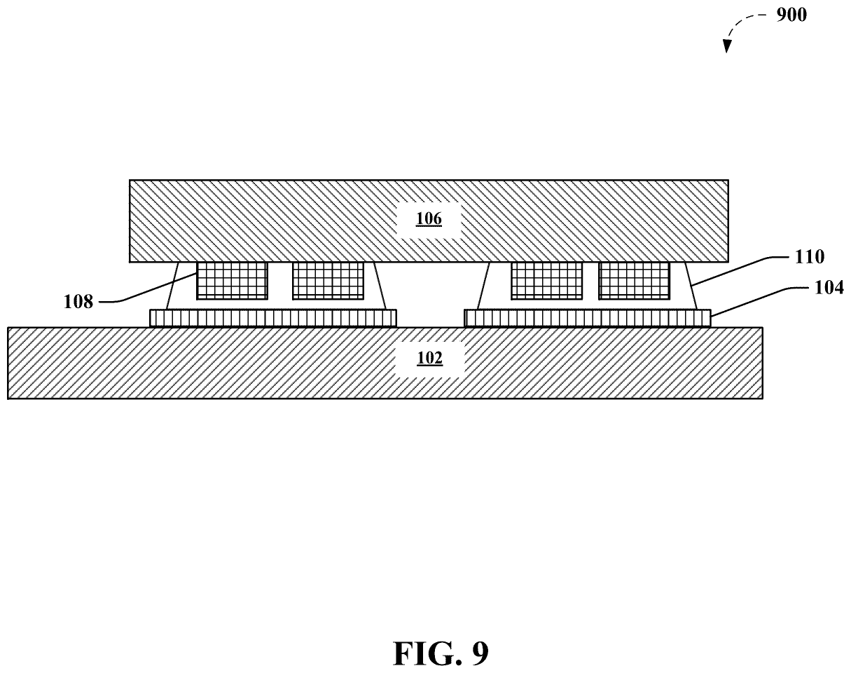

FIG. 9 depicts non-limiting embodiments 900 of the subject disclosure regarding non-metallic LED interconnects and packages, according to aspects of the subject disclosure. Thus, FIG. 9 depicts an exemplary LED package 100 where like reference characters are used to describe like components or structures of exemplary LED package 100. Accordingly, in various non-limiting embodiments, the disclosed subject matter can employ shaped electrodes (e.g., shaped electrodes 602, 604, 606, 608, 610, 612) as described herein with interconnect or bonding materials 110 comprising conductive metal-based adhesive (e.g., a metallic particle filled conductive adhesive), such as silver-filled, electrically conductive adhesive that can mechanically affix and electrically couple the shaped electrodes (e.g., shaped electrodes 602, 604, 606, 608, 610, 612) to the LED package substrate pads 104 LED package substrate 102. In a non-limiting example, an exemplary silver-filled, electrically conductive can comprise a silver-based adhesive comprising a polymer adhesive with a silver particle fill percentage of greater than 75 percent by weight, which can facilitate a balance of electrical conductivity, thermal conductivity, and joint/bond adhesion strength.

As described above, exemplary interconnect or bonding materials 110 comprising conductive metal-based adhesive (e.g., a metallic particle filled conductive adhesive), such as silver-filled, electrically conductive adhesive can facilitate a flexible joint/bond formation of exemplary LED package 100, between LED package substrate pads 104 of LED package substrate 102 and flip chip LED device 106 electrodes or terminals 108 of flip chip LED device 106 that accommodates LED package 100 components having otherwise incompatible differences in CTE, and low bonding temperatures (e.g., less than about 180° C.), which might otherwise cause exemplary LED packaging 100 component materials thermal degradation, as described above, regarding formation of metallic-based solder joint/bonds.

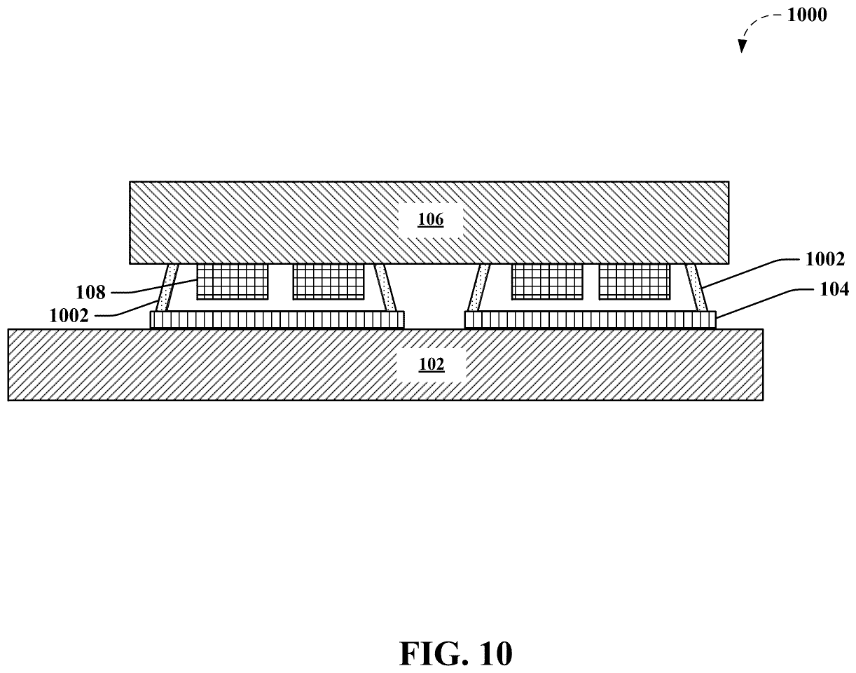

FIG. 10 depicts further non-limiting embodiments 1000 of the subject disclosure regarding non-metallic LED interconnects and packages, according to aspects of the subject disclosure. As in FIG. 9, FIG. 10 depicts an exemplary LED package 100 where like reference characters are used to describe like components or structures of exemplary LED package 100. Accordingly, in various non-limiting embodiments, the disclosed subject matter can employ a barrier coating 1002 on the interconnect or bonding materials 110 comprising conductive metal-based adhesive (e.g., a metallic particle filled conductive adhesive), such as silver-filled, electrically conductive adhesive between LED device (e.g., flip chip LED device 106) and the LED package substrate (e.g., LED package substrate pads 104 LED and/or package substrate 102) that can facilitate inhibiting moisture and air contact to the interconnect or bonding materials 110 comprising conductive metal-based adhesive (e.g., a metallic particle filled conductive adhesive), such as silver-filled, electrically conductive adhesive. While FIG. 10 depicts barrier coating 1002 terminating at the LED package substrate pads 104 LED of package substrate 102, it can be understood that the barrier coating 1002 can extend to the package substrate 102, fill the area between the two LED package substrate pads 104 LED of package substrate 102, and so on.

In a non-limiting aspect, an exemplary barrier coating 1002 can protect against silver migration as described herein, which would otherwise be accelerated by air/moisture/ionic contamination. In another non-limiting aspect, an exemplary barrier coating 1002 can be deposited around the interconnect or bonding materials 110 comprising conductive metal-based adhesive (e.g., a metallic particle filled conductive adhesive), such as silver-filled, electrically conductive adhesive by way of dispensing, jetting, coating, lamination, molding process using resin material with low moisture/air permeability. In yet another non-limiting aspect, an exemplary barrier coating 1002 can be around the interconnect or bonding materials 110 comprising conductive metal-based adhesive (e.g., a metallic particle filled conductive adhesive), such as silver-filled, electrically conductive adhesive also by way of atomic layer deposition (ALD) by depositing layers of material which has low moisture/air permeability, including, but not limited to silicon dioxide (SiO₂), silicon nitride (SiN), aluminum oxide (Al₂O₃), or titanium oxide (TiO₂).

Accordingly, exemplary interconnect or bonding materials 110 comprising conductive metal-based adhesive (e.g., a metallic particle filled conductive adhesive), such as silver-filled, electrically conductive adhesive can mitigate or prevent, in conjunction with a protective, moisture/air barrier coating on the exemplary interconnect or bonding materials 110 comprising conductive metal-based adhesive (e.g., a metallic particle filled conductive adhesive), metal migration in the exemplary interconnect or bonding materials 110, which could otherwise lead to exemplary LED package 100 failure, as described above, regarding formation of metallic particle filled conductive adhesive joint/bonds and metallic-based solder joint/bonds (e.g., sintered silver joint/bond).

Accordingly, in an aspect, non-limiting embodiments of the disclosed subject matter can employ a shaped electrode (e.g., shaped electrodes 602, 604, 606, 608, 610, 612) attached to an LED device (e.g., flip chip LED device 106). In another non-limiting aspect, the shaped electrode (e.g., shaped electrodes 602, 604, 606, 608, 610, 612) comprises a lateral shape that is selected to resist lateral shear forces (e.g., lateral shear forces 402, 502) applied between the LED device (e.g., flip chip LED device 106) and a LED package substrate (e.g., LED package substrate 102), based an increase in perimeter (e.g., via a perimeter increasing protrusion such as a perimeter increasing protrusion of convex portion 702) of a surface opposite the LED device (e.g., flip chip LED device 106) associated with the shaped electrode (e.g., shaped electrodes 602, 604, 606, 608, 610, 612). As can be understood, the increase in perimeter (e.g., via a perimeter increasing protrusion such as a perimeter increasing protrusion of convex portion 702) of a surface opposite the LED device (e.g., flip chip LED device 106 is an increase relative to a standard shaped electrode (e.g., square shaped, rectangular shaped, round shaped, oval shaped, polygonal shaped, and so on). In yet another non-limiting aspect, the lateral shape that is selected to resist lateral shear forces (e.g., lateral shear forces 402, 502) applied between the LED device (e.g., flip chip LED device 106) and a LED package substrate (e.g., LED package substrate 102) can comprise a convex portion (e.g., a perimeter increasing protrusion of convex portion 702 or similar) of the perimeter of the surface opposite the LED device (e.g., flip chip LED device 106).

It can be further understood that the shaped electrode (e.g., shaped electrodes 602, 604, 606, 608, 610, 612) can facilitate anchorage of the interconnect or bonding materials 110 comprising conductive metal-based adhesive (e.g., a metallic particle filled conductive adhesive), such as silver-filled, electrically conductive adhesive into the perimeter increasing protrusion of convex portion 702 of the shaped electrode (e.g., shaped electrodes 602, 604, 606, 608, 610, 612) during the bonding process. As described above, this anchorage can enhance the joint/bond resistance against the lateral forces 402, 502.

In further non-limiting embodiments, the disclosed subject matter provides thickness profiles that increase surface area of the shaped electrode (e.g., shaped electrodes 602, 604, 606, 608, 610, 612) in a direction orthogonal to the LED device (e.g., flip chip LED device 106), based on the thickness profiles in views 806, 808, and 810 being non-orthogonal to the LED device (e.g., flip chip LED device 106) to facilitate bonding between the shaped electrode (e.g., shaped electrodes 602, 604, 606, 608, 610, 612) and LED package substrate pads 104 of LED package substrate 102 via the interconnect or bonding materials 110 comprising conductive metal-based adhesive (e.g., a metallic particle filled conductive adhesive), such as silver-filled, electrically conductive adhesive, with enhanced joint/bond force between the shaped electrode (e.g., shaped electrodes 602, 604, 606, 608, 610, 612) and the interconnect or bonding materials 110 comprising conductive metal-based adhesive (e.g., a metallic particle filled conductive adhesive), such as silver-filled, electrically conductive adhesive, without increasing the depth/thickness of the shaped electrode (e.g., shaped electrodes 602, 604, 606, 608, 610, 612) to the datum of the LED device (e.g., flip chip LED device 106) (e.g., equal or greater than about 3 microns).

In another non-limiting aspect, an exemplary convex portion (e.g., perimeter increasing protrusions of convex portion 702) of the perimeter of the surface opposite the LED device (e.g., flip chip LED device 106) can be located along an edge or at an intersection of adjacent edges of the perimeter of the surface opposite the LED device (e.g., flip chip LED device 106), for example, as described above regarding FIG. 6. In another still non-limiting aspect, an exemplary convex portion (e.g., perimeter increasing protrusions of convex portion 702) of the perimeter of the surface opposite the LED device (e.g., flip chip LED device 106) provides the increase in perimeter associated with the shaped electrode (e.g., shaped electrodes 602, 604, 606, 608, 610, 612), for example, as further described above regarding FIG. 6. In yet another non-limiting aspect, an exemplary shaped electrode (e.g., shaped electrodes 602, 604, 606, 608, 610, 612) can further comprise a top surface located adjacent to the LED device (e.g., flip chip LED device 106) and a bottom surface for bonding to the pad (e.g., LED package substrate pad 104) on the LED package substrate (e.g., LED package substrate 102) with a thickness profile that has a cross-section having unequal dimensions at the top surface and bottom surface or a convex profile between the top surface and the bottom surface, for example, as further described above regarding FIG. 6.

In further non-limiting embodiments, the disclosed subject matter can employ shaped electrodes (e.g., shaped electrodes 602, 604, 606, 608, 610, 612) as described herein with interconnect or bonding materials 110 comprising conductive metal-based adhesive (e.g., a metallic particle filled conductive adhesive), such as silver-filled, electrically conductive adhesive that can mechanically affix and electrically couple the shaped electrodes (e.g., shaped electrodes 602, 604, 606, 608, 610, 612) to the LED package substrate pads 104 LED package substrate 102. In a non-limiting example, an exemplary silver-filled, electrically conductive can comprise a silver-based adhesive comprising a polymer adhesive with a silver particle fill percentage of greater than 75 percent by weight, which can facilitate a balance of electrical conductivity, thermal conductivity, and joint/bond adhesion strength.

In another non-limiting aspect, an exemplary conductive metal-based adhesive (e.g., interconnect or bonding materials 110 comprising conductive metal-based adhesive, such as silver-filled, electrically conductive adhesive) can encompass the shaped electrode (e.g., shaped electrodes 602, 604, 606, 608, 610, 612) between the LED device (e.g., flip chip LED device 106) and the LED package substrate (e.g., LED package substrate 102), for example, as described above regarding FIG. 9.

In still further non-limiting embodiments, the disclosed subject matter can employ a barrier coating 1002 on the interconnect or bonding materials 110 comprising conductive metal-based adhesive (e.g., a metallic particle filled conductive adhesive), such as silver-filled, electrically conductive adhesive between LED device (e.g., flip chip LED device 106) and the LED package substrate (e.g., LED package substrate pads 104 LED and/or package substrate 102) that can facilitate inhibiting moisture and air contact to the interconnect or bonding materials 110 comprising conductive metal-based adhesive (e.g., a metallic particle filled conductive adhesive), such as silver-filled, electrically conductive adhesive. While FIG. 10 depicts barrier coating 1002 terminating at the LED package substrate pads 104 LED of package substrate 102, it can be understood that the barrier coating 1002 can extend to the package substrate 102, fill the area between the two LED package substrate pads 104 LED of package substrate 102, and so on.

In a non-limiting aspect, an exemplary barrier coating 1002 can protect against silver migration as described herein, which would otherwise be accelerated by air/moisture/ionic contamination. In another non-limiting aspect, an exemplary barrier coating 1002 can be deposited around the interconnect or bonding materials 110 comprising conductive metal-based adhesive (e.g., a metallic particle filled conductive adhesive), such as silver-filled, electrically conductive adhesive by way of dispensing, jetting, coating, lamination, molding process using resin material with low moisture/air permeability. In yet another non-limiting aspect, an exemplary barrier coating 1002 can be around the interconnect or bonding materials 110 comprising conductive metal-based adhesive (e.g., a metallic particle filled conductive adhesive), such as silver-filled, electrically conductive adhesive also by way of atomic layer deposition (ALD) by depositing layers of material which has low moisture/air permeability, including, but not limited to silicon dioxide (SiO₂), silicon nitride (SiN), aluminum oxide (Al₂O₃), or titanium oxide (TiO₂).

Accordingly, exemplary interconnect or bonding materials 110 comprising conductive metal-based adhesive (e.g., a metallic particle filled conductive adhesive), such as silver-filled, electrically conductive adhesive can mitigate or prevent, in conjunction with a protective, moisture/air barrier coating on the exemplary interconnect or bonding materials 110 comprising conductive metal-based adhesive (e.g., a metallic particle filled conductive adhesive), metal migration in the exemplary interconnect or bonding materials 110, which could otherwise lead to exemplary LED package 100 failure, as described above, regarding formation of metallic particle filled conductive adhesive joint/bonds and metallic-based solder joint/bonds (e.g., sintered silver joint/bond).

In other non-limiting embodiments, the disclosed subject matter provides an exemplary light-emitting diode (LED) interconnect, which can comprise a shaped electrode (e.g., shaped electrodes 602, 604, 606, 608, 610, 612) attached to an LED device (e.g., flip chip LED device 106), as further described herein regarding FIG. 6. In a non-limiting aspect, an exemplary shaped electrode (e.g., shaped electrodes 602, 604, 606, 608, 610, 612) can comprise a lateral shape that is selected to resist lateral shear forces (e.g., lateral shear forces 402, 502) applied between the LED device (e.g., flip chip LED device 106) and an LED device (e.g., flip chip LED device 106) substrate (e.g., LED package substrate 102), based on an increase in perimeter of a surface opposite the LED device (e.g., flip chip LED device 106) associated with the shaped electrode (e.g., shaped electrodes 602, 604, 606, 608, 610, 612) relative to a square or a rectangular shaped electrode (or other standard shape without the perimeter increasing protrusion of convex portion 702), for example, as further described above regarding FIGS. 6-7.

In a non-limiting aspect, an exemplary lateral shape can comprise a convex portion (e.g., a perimeter increasing protrusion of convex portion 702) of the perimeter of the surface opposite the LED device (e.g., flip chip LED device 106), and wherein the convex portion (e.g., a perimeter increasing protrusion of convex portion 702) of the perimeter of the surface opposite the LED device (e.g., flip chip LED device 106) is located along an edge or at an intersection of adjacent edges of the perimeter of the surface opposite the LED device (e.g., flip chip LED device 106).

In further non-limiting embodiments, the disclosed subject matter can employ a conductive metal-based adhesive (e.g., interconnect or bonding materials 110 comprising conductive metal-based adhesive, such as silver-filled, electrically conductive adhesive) that mechanically affixes and electrically couples the shaped electrode (e.g., shaped electrodes 602, 604, 606, 608, 610, 612) to a pad (e.g., LED package substrate pad 104) on the LED device (e.g., flip chip LED device 106) substrate (e.g., LED package substrate 102), for example, as further described above regarding FIG. 9.

In another non-limiting aspect, an exemplary conductive metal-based adhesive (e.g., interconnect or bonding materials 110 comprising conductive metal-based adhesive, such as silver-filled, electrically conductive adhesive) comprises a silver-based adhesive comprising silver particle fill percentage of greater than 75 percent by weight. In still another non-limiting aspect, an exemplary shaped electrode (e.g., shaped electrodes 602, 604, 606, 608, 610, 612) can comprise a thickness profile that is selected to increase surface area, in a direction orthogonal to the LED device (e.g., flip chip LED device 106), of the shaped electrode (e.g., shaped electrodes 602, 604, 606, 608, 610, 612) for bonding of the shaped electrode (e.g., shaped electrodes 602, 604, 606, 608, 610, 612) and conductive metal-based adhesive (e.g., interconnect or bonding materials 110 comprising conductive metal-based adhesive, such as silver-filled, electrically conductive adhesive) to the LED device (e.g., flip chip LED device 106) substrate (e.g., LED package substrate 102), based on the thickness profile being non-orthogonal to the LED device (e.g., flip chip LED device 106) substrate (e.g., LED package substrate 102), for example, as further described above regarding FIGS. 8-9.

In further non-limiting embodiments, the disclosed subject matter can employ an exemplary barrier coating (e.g., barrier coating 1002) on the conductive metal-based adhesive (e.g., interconnect or bonding materials 110 comprising conductive metal-based adhesive, such as silver-filled, electrically conductive adhesive) between the LED device (e.g., flip chip LED device 106) and the LED package substrate (e.g., LED package substrate 102) that inhibits moisture and air contact to the conductive metal-based adhesive (e.g., interconnect or bonding materials 110 comprising conductive metal-based adhesive, such as silver-filled, electrically conductive adhesive), for example, as further described above regarding FIG. 10.

In another non-limiting aspect, an exemplary barrier coating (e.g., barrier coating 1002) can comprise a resin application or a deposition of silicon dioxide (SiO₂), silicon nitride (SiN), aluminum oxide (Al₂O₃), or titanium oxide (TiO₂) that inhibits moisture and air contact to the conductive metal-based adhesive (e.g., interconnect or bonding materials 110 comprising conductive metal-based adhesive, such as silver-filled, electrically conductive adhesive).

In other non-limiting embodiments, the disclosed subject matter provides an exemplary light-emitting diode (LED) interconnect, that can comprise an electrode means (e.g., shaped electrodes 602, 604, 606, 608, 610, 612) for resisting lateral shear forces (e.g., lateral shear forces 402, 502) applied between an LED device (e.g., flip chip LED device 106) and an LED device (e.g., flip chip LED device 106) substrate (e.g., LED package substrate 102), based on an increase in perimeter of a surface opposite the LED device (e.g., flip chip LED device 106) associated with the shaped electrode (e.g., shaped electrodes 602, 604, 606, 608, 610, 612) relative to a square or a rectangular shaped electrode (or other standard shape without the perimeter increasing protrusion of convex portion 702), for example, as further described above regarding FIGS. 6-7.

In a non-limiting aspect, exemplary electrode means (e.g., shaped electrodes 602, 604, 606, 608, 610, 612) can comprise a lateral shape that is selected to resist lateral shear forces (e.g., lateral shear forces 402, 502) applied between the LED device (e.g., flip chip LED device 106) and an LED device (e.g., flip chip LED device 106) substrate (e.g., LED package substrate 102) to provide the increase in perimeter (e.g., via exemplary perimeter increasing protrusion of convex portion 702) of the surface opposite the LED device (e.g., flip chip LED device 106), for example, as further described above regarding FIGS. 6-7. In another non-limiting aspect, exemplary electrode means (e.g., shaped electrodes 602, 604, 606, 608, 610, 612) can comprise a convex portion (e.g., perimeter increasing protrusion of convex portion 702) of the perimeter of the surface opposite the LED device (e.g., flip chip LED device 106) located along an edge or at an intersection of adjacent edges of the perimeter of the surface opposite the LED device (e.g., flip chip LED device 106), for example, as further described above regarding FIGS. 6-7.

In further non-limiting embodiments, the disclosed subject matter can employ a conductive adhesive means (e.g., interconnect or bonding materials 110 comprising conductive metal-based adhesive, such as silver-filled, electrically conductive adhesive) for mechanically affixing and electrically coupling the electrode means (e.g., shaped electrodes 602, 604, 606, 608, 610, 612) to a pad (e.g., LED package substrate pad 104) on the LED device (e.g., flip chip LED device 106) substrate (e.g., LED package substrate 102), for example, as further described above regarding FIG. 9.

In a non-limiting aspect, exemplary conductive adhesive means (e.g., interconnect or bonding materials 110 comprising conductive metal-based adhesive, such as silver-filled, electrically conductive adhesive) can comprise a silver-based adhesive or a polymer adhesive comprising silver particle fill percentage of greater than 75 percent by weight. In further non-limiting aspects, exemplary electrode means (e.g., shaped electrodes 602, 604, 606, 608, 610, 612) can comprise a thickness profile that is selected to increase surface area, in a direction orthogonal to the LED device (e.g., flip chip LED device 106), of the electrode means (e.g., shaped electrodes 602, 604, 606, 608, 610, 612) for bonding of the electrode means (e.g., shaped electrodes 602, 604, 606, 608, 610, 612) and conductive adhesive means (e.g., interconnect or bonding materials 110 comprising conductive metal-based adhesive, such as silver-filled, electrically conductive adhesive) to the LED device (e.g., flip chip LED device 106) substrate (e.g., LED package substrate 102), based on the thickness profile being non-orthogonal to the LED device (e.g., flip chip LED device 106) substrate (e.g., LED package substrate 102), for example, as further described above, regarding FIG. 8.

In still further non-limiting embodiments, the disclosed subject matter can employ an exemplary sealing means (e.g., barrier coating 1002) for encapsulating the conductive adhesive means (e.g., interconnect or bonding materials 110 comprising conductive metal-based adhesive, such as silver-filled, electrically conductive adhesive) between the LED device (e.g., flip chip LED device 106) and the LED package substrate (e.g., LED package substrate 102) for inhibiting moisture and air contact to the conductive adhesive means (e.g., interconnect or bonding materials 110 comprising conductive metal-based adhesive, such as silver-filled, electrically conductive adhesive), for example, as further described above regarding FIG. 10. For instance, in a non-limiting aspect, an exemplary sealing means (e.g., barrier coating 1002) can comprise a resin application or a deposition of at least one of silicon dioxide (SiO₂), silicon nitride (SiN), aluminum oxide (Al₂O₃), or titanium oxide (TiO₂) that inhibits moisture and air contact to the conductive adhesive means (e.g., interconnect or bonding materials 110 comprising conductive metal-based adhesive, such as silver-filled, electrically conductive adhesive).

What has been described above includes examples of the embodiments of the subject disclosure. It is, of course, not possible to describe every conceivable combination of configurations, components, and/or methods for purposes of describing the claimed subject matter, but it is to be appreciated that many further combinations and permutations of the various embodiments are possible. Accordingly, the claimed subject matter is intended to embrace all such alterations, modifications, and variations that fall within the spirit and scope of the appended claims. While specific embodiments and examples are described in subject disclosure illustrative purposes, various modifications are possible that are considered within the scope of such embodiments and examples, as those skilled in the relevant art can recognize. For example, while embodiments of the subject disclosure are described herein in the context of electrical interconnects (e.g., such as LED non-metallic interconnects), it can be appreciated that the subject disclosure is not so limited. For instance, as further detailed herein, various exemplary implementations can be applied to other areas of electronic structures, devices, systems, and methods, without departing from the subject matter described herein.

In addition, the words “example” or “exemplary” is used herein to mean serving as an example, instance, or illustration. Any aspect or design described herein as “exemplary” is not necessarily to be construed as preferred or advantageous over other aspects or designs. Rather, use of the word, “exemplary,” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

In addition, while an aspect may have been disclosed with respect to only one of several embodiments, such feature may be combined with one or more other features of the other embodiments as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

What is claimed is:

1. A light-emitting diode (LED) package, comprising:
at least one shaped electrode attached to an LED device, wherein the at least one shaped electrode comprises at least one of a set of lateral shapes that are selected to resist lateral shear forces applied between the LED device and a LED package substrate, based at least in part on an increase in perimeter of a surface opposite the LED device associated with the at least one shaped electrode relative to a square or a rectangular shaped electrode, and wherein the at least one of the set of lateral shapes comprises at least one convex portion of the perimeter of the surface opposite the LED device;
a conductive metal-based adhesive that mechanically affixes and electrically couples the at least one shaped electrode to at least one pad on the LED package substrate; and
a barrier coating on at least the conductive metal-based adhesive between at least the LED device and the LED package substrate that inhibits moisture and air contact to the conductive metal-based adhesive, wherein the at least one shaped electrode further comprises at least one of a set of thickness profiles that are selected to increase surface area, in a direction orthogonal to the LED device, of the at least one shaped electrode for bonding of the at least one shaped electrode and conductive metal-based adhesive and the LED package substrate, based at least in part on the set of thickness profiles being non-orthogonal to the LED device.

2. The LED package of claim 1, wherein the conductive metal-based adhesive encompasses the at least one shaped electrode between at least the LED device and the LED package substrate.

3. The LED package of claim 1, wherein each lateral shape of the set of lateral shapes comprises the at least one convex portion of the perimeter of the surface opposite the LED device.

4. The LED package of claim 1, wherein the at least one convex portion of the perimeter of the surface opposite the LED device is located at least one of along an edge or at an intersection of adjacent edges of the perimeter of the surface opposite the LED device.

5. The LED package of claim 1, wherein the at least one convex portion of the perimeter of the surface opposite the LED device provides the increase in perimeter associated with the at least one shaped electrode.

6. The LED package of claim 1, wherein the at least one shaped electrode further comprises a top surface located adjacent to the LED device and a bottom surface for bonding to the at least one pad on the LED package substrate, and wherein the set of thickness profiles comprises at least one of a cross-section having unequal dimensions at the top surface and bottom surface or a convex profile between the top surface and the bottom surface.

7. The LED package of claim 1, wherein the conductive metal-based adhesive comprises a silver-based adhesive.

8. The LED package of claim 7, wherein the silver-based adhesive comprises a polymer adhesive comprising silver particle fill percentage of greater than seventy-five (75) percent by weight.

9. The LED package of claim 1, wherein the barrier coating comprises a resin application that inhibits moisture and air contact to the conductive metal-based adhesive.

10. The LED package of claim 1, wherein the barrier coating comprises at least one of a silicon dioxide (SiO2), silicon nitride (SiN), aluminum oxide (Al2O3), or titanium oxide (TiO2) deposition that inhibits moisture and air contact to the conductive metal-based adhesive.

11. A light-emitting diode (LED) interconnect, comprising:
at least one shaped electrode attached to an LED device, wherein the at least one shaped electrode comprises at least one of a set of lateral shapes that are selected to resist lateral shear forces applied between the LED device and an LED device substrate, based at least in part on an increase in perimeter of a surface opposite the LED device associated with the at least one shaped electrode relative to a square or a rectangular shaped electrode;
a conductive metal-based adhesive that mechanically affixes and electrically couples the at least one shaped electrode to at least one pad on the LED device substrate, wherein the at least one shaped electrode further comprises at least one of a set of thickness profiles that are selected to increase surface area, in a direction orthogonal to the LED device, of the at least one shaped electrode for bonding of the at least one shaped electrode and conductive metal-based adhesive to the LED device substrate, based at least in part on the set of thickness profiles being non-orthogonal to the LED device substrate; and
a barrier coating on at least the conductive metal-based adhesive between at least the LED device and the LED package substrate that inhibits moisture and air contact to the conductive metal-based adhesive.

12. The LED interconnect of claim 11, wherein each lateral shape of the set of lateral shapes comprises at least one convex portion of the perimeter of the surface opposite the LED device, and wherein the at least one convex portion of the perimeter of the surface opposite the LED device is located at least one of along an edge or at an intersection of adjacent edges of the perimeter of the surface opposite the LED device.

13. The LED interconnect of claim 11, wherein the barrier coating comprises at least one of a resin application or a deposition of at least one of silicon dioxide (SiO2), silicon nitride (SiN), aluminum oxide (Al2O3), or titanium oxide (TiO2) that inhibits moisture and air contact to the conductive metal-based adhesive.

14. The LED interconnect of claim 11, wherein the conductive metal-based adhesive comprises a silver-based adhesive comprising silver particle fill percentage of greater than seventy-five (75) percent by weight.

15. A light-emitting diode (LED) interconnect, comprising:
an electrode means for resisting lateral shear forces applied between an LED device and an LED device substrate, based at least in part on an increase in perimeter of a surface opposite the LED device associated with the electrode means relative to a square or a rectangular shaped electrode;
a conductive adhesive means for mechanically affixing and electrically coupling the electrode means to at least one pad on the LED device substrate; and
a sealing means for encapsulating the conductive adhesive means between at least the LED device and the LED device substrate and for inhibiting moisture and air contact to the conductive adhesive means.

16. The LED interconnect of claim 15, wherein the electrode means comprises at least one of a set of lateral shapes that are selected to resist lateral shear forces applied between the LED device and the LED device substrate to provide the increase in perimeter of the surface opposite the LED device, and wherein each lateral shape of the set of lateral shapes comprises at least one convex portion of the perimeter of the surface opposite the LED device.

17. The LED interconnect of claim 16, wherein the at least one convex portion of the perimeter of the surface opposite the LED device is located at least one of along an edge or at an intersection of adjacent edges of the perimeter of the surface opposite the LED device.

18. The LED interconnect of claim 15, wherein the electrode means further comprises at least one of a set of thickness profiles that are selected to increase surface area, in a direction orthogonal to the LED device, of the electrode means for bonding of the electrode means and conductive adhesive means to the LED device substrate, based at least in part on the set of thickness profiles being non-orthogonal to the LED device substrate.

19. The LED interconnect of claim 15, wherein the conductive adhesive means comprises at least one of a silver-based adhesive or a polymer adhesive comprising silver particle fill percentage of greater than seventy-five (75) percent by weight.

20. The LED interconnect of claim 15, wherein the sealing means comprises at least one of a resin application or a deposition of at least one of silicon dioxide (SiO2), silicon nitride (SiN), aluminum oxide (Al2O3), or titanium oxide (TiO2) that inhibits moisture and air contact to the conductive adhesive means.
